(19) United States
(12) Patent Application Publication
(10) Pub. No.: US 2014/0137935 A1
(43) Pub. Date: May 22, 2014

(54) BACK SHEET FOR SOLAR CELLS, AND SOLAR CELL USING SAME

(71) Applicants: Yousuke Hiroi, Ibaraki (JP); Seiichiro Iida, Ibaraki (JP)

(72) Inventors: Yousuke Hiroi, Ibaraki (JP); Seiichiro Iida, Ibaraki (JP)

(73) Assignee: YUPO CORPORATION, Tokyo (JP)

(21) Appl. No.: 14/130,752

(22) PCT Filed: Jul. 6, 2012
(86) PCT No.: PCT/JP2012/067276

§ 371 Date: Jan. 3, 2014

(30) Foreign Application Priority Data
Jul. 7, 2011 (JP) 2011-150790

(51) Int. Cl. H01L 31/048

(52) U.S. Cl. CPC H01L 31/0487
USPC 136/256

(57) ABSTRACT

A solar-cell back sheet comprising a laminate of an adhesive layer (2) containing 50 to 100% by weight of a thermoplastic resin and 0 to 50% by weight of an inorganic filler or an organic filler, and a base layer (1) containing 30 to 95% by weight of a polypropylene resin, and 5 to 70% by weight of an inorganic filler or an organic filler, and being stretched in at least one direction with a porosity of 55% or less, in which a reflectance for light of 750 nm wavelength is 90% or more and a partial discharge voltage per micrometer is 7.5 V or more, is excellent in partial discharge voltage, and can be reduced in thickness, and has excellent adhesion for a sealing material.

### TECHNICAL FIELD

The present invention relates to back sheets used for protection of a solar cell module. Specifically, the invention relates to a back sheet formed of a resin laminate disposed on a sealing material on the opposite side from the light incident surface of a solar cell module, and having excellent reflectance that allows the incoming sunlight through the module to be efficiently reflected toward the voltaic element side and thereby improves power efficiency, excellent voltage resistance that prevents a leakage of generated electricity, and excellent adhesion for the sealing material, preventing a performance drop even after long outdoor use of the solar cell. The present invention also relates to solar cells that use such a back sheet.

### BACKGROUND ART

Solar power generates electricity through the direct conversion of the sunlight energy into power using a solar cell, and has attracted interest as a clean energy source that does not produce wastes and emissions, and as an emergency power supply that does not depend on the supply of power from an electric utility. In recent years, use of solar power has been spreading in the consumer product level. The demand for solar cells has been increasing globally because of the low operation and maintenance costs.

The solar cell uses assemblies of photovoltaic elements oriented and sealed with a sealing material (sealant) to make a unit solar cell module. Ethylene-vinyl acetate copolymer resin is commonly used as the sealing material.

While sealing materials using ethylene-vinyl acetate copolymer resin excel in cold resistance and waterfastness, these materials have certain drawbacks, including high permeability for gases such as oxygen and water vapor, which easily corrodes the voltaic elements, and degrades and discolors the sealant resin itself under the effect of the gas, and the low melting points, which easily causes deformation at high temperatures. Another drawback is that the resin is polar, and has low voltage resistance. These drawbacks are typically overcome by the provision of protective sheets on the top and back surfaces of a solar cell module. In present invention, the protective sheet on the back-surface side will be called a back sheet.

A solar-cell back sheet has been studied for improvement from various perspectives, including water vapor permeation, light reflectance, dimension stability, partial discharge voltage, and discoloration after a weathering test. Often, a polyester-based film is used as core material, and fluororesin films are laminated on the both sides of the core. However, because fluororesin films are flexible and weak in mechanical strength, and are expensive, a variety of back sheets are proposed that use a laminate of various performance polyester-based films.

Specifically, for example, it has been proposed to use polyester resins of improved weather resistance (for example, Patent Document 1), laminate gas barrier films for improved moisture resistance, and laminate electrically insulating films and foaming layers for improved partial discharge voltage (for example, Patent Document 2), provide an antistatic layer on a film surface layer to lower surface resistivity and improve partial discharge voltage (for example, Patent Document 3), and adjust the number average molecular weight of the polyethylene terephthalate used, or the content of titanium oxide particles to improve delamination strength (for example, Patent Document 4). At present, back sheets that mainly use polyester films are mainstream.

### CITATION LIST

### Patent Document

Patent Document 1: JP-A-2002-134771
Patent Document 2: JP-A-2006-253264
Patent Document 3: JP-A-2009-147063
Patent Document 4: JP-A-2010-254779

### SUMMARY OF THE INVENTION

### Problems that the Invention is to Solve

The spread of the solar cell comes with increased demands for cheaper costs of generating electricity. Accordingly, there is a need for further improving power efficiency, and further lowering the cost of each component of a solar cell module.

Taking power efficiency for example, improved power efficiency can be realized by effectively reflecting and reusing the incident light by the back sheet. A typical back sheet formed of polyester films has a reflectance of about 80 to 90% at 750 nm wavelength. If the reflectance for the same light could be increased to about 98%, the maximum module output would be expected to improve by about 1.5%, and it would be possible to further improve the power exchange efficiency of the solar cell. As for the polyester film, the material is inherently prone to hydrolysis, and tends to degrade when used outside for extended time periods. Further, the polyester film tends to undergo discoloration, such as yellowing, under short-wavelength light such as ultraviolet rays, and lose some of the ability to reflect light.

One obstacle to the spread of the solar cell is the high initial cost, and the costs of the solar cell components need to be lowered. Specifically, for the protection of solar cell modules from damages caused by charges, a solar-cell back sheet needs to withstand a partial discharge voltage of 700V or more, or 1,000 V or more, depending on the power capacity. The polyesters used in Patent Documents 1 to 4 are resins that have polarity in the molecular structure, and have relatively high dielectric constants. For this reason, the polyester films need to be laminated with other materials, or the film thickness itself needs to be increased to meet the foregoing requirements. This inevitably raises cost.

On the other hand, because the solar cell is intended for long outdoor use, detachment tends to occur at the interface between the sealing material and the back sheet of the solar cell when these members undergo dimensional changes such as thermal expansion and contraction due to daytime or seasonal temperature fluctuations. The solar cell module is no longer protected by the back sheet when such detachment occurs at the interface between the solar-cell back sheet and the sealing material, and the cell portions of the solar cell degrade as the moisture permeates. The adhesion between the sealing material and the back sheet is indeed an important factor in maintaining quality in solar cell production, and further improvements are needed for the adhesion between these members.

The present invention is intended to solve the foregoing problems, and it is an object of the present invention to provide a solar-cell back sheet that has high reflectance even by itself, and that excels in partial discharge voltage, and can be reduced in thickness. Another object of the present invention is to provide a solar-cell back sheet that has excellent adhesion for a sealing material.

### Means for Solving the Problems

The present inventors conducted intensive studies, and found that a back sheet provided as a laminate of a polypropylene-based resin base layer having a specific porosity, and a thermoplastic resin adhesive layer having a specific porosity has desirable reflectance and partial discharge voltage, and excellent adhesion for a sealing material, and can solve the foregoing problems. Specifically, the present invention has been completed through a laminated solar-cell back sheet of the following characteristics.

More specifically, the present invention is concerned with the following solar-cell back sheet.

[1] A solar-cell back sheet comprising a laminate of at least an adhesive layer and a base layer,

wherein the adhesive layer contains 50 to 100% by weight of a thermoplastic resin, and 0 to 50% by weight of at least one of an inorganic filler and an organic filler,

wherein the base layer contains 30 to 95% by weight of a polypropylene resin, and 5 to 70% by weight of at least one of an inorganic filler and an organic filler, and is stretched in at least one direction, and has a porosity of 55% or less, and

wherein the laminate has a reflectance of 90% or more for light of 750 nm wavelength at a surface on the side of the adhesive layer as measured according to the method described under condition d of JIS-Z8722, and a partial discharge voltage of 7.5 V or more per micrometer of laminate thickness as measured according to the method described in IEC-60664-1.

[2] It is preferable that the base layer have a porosity of 3 to 53%.

[3] It is preferable that that base layer have a thickness of 70 to 250 μm.

[4] It is preferable that the inorganic filler and the organic filler in the base layer have an average particle diameter or an average dispersion particle diameter of 0.05 to 0.9 μm.

[5] It is preferable that the adhesive layer have a porosity of 0 to 3%.

[6] It is preferable that thermoplastic resin in the adhesive layer be at least one of a polyethylene resin having a melting point of less than 150° C., a random polypropylene resin having a melting point of less than 150° C., and an ethylene-vinyl acetate copolymer resin having a melting point of less than 150° C.

[7] It is preferable that the thermoplastic resin in the adhesive layer be alternatively a polypropylene resin having a melting point of 150° C. or more.

[8] It is preferable in the case of [7] that the back sheet include a surface treatment layer of primarily acrylic acid ester-based resin or polyethyleneimine-based resin on the surface on the side of the adhesive layer.

[9] It is preferable that the surface of the side of the adhesive layer be in contact with a sealing material made of ethylene-vinyl acetate copolymer resin.

[10] It is preferable that the peel force between the adhesive layer and the sealing material be 20 N/25 mm or more.

[11] It is preferable that the back sheet further include a resin film containing at least one of a polyester-based resin and a fluororesin, or an aluminum foil laminated on one surface or both surfaces of the laminate.

### Advantage of the Invention

The solar-cell back sheet of the present invention excels in light reflectance, and can effectively reuse the incident light on a solar cell module, and improve the power exchange efficiency of the solar cell. The solar-cell back sheet of the present invention includes a base layer made of nonpolar polypropylene resin, and has sufficiently high partial discharge voltage by itself. This makes it possible to reduce the sheet thickness, and effectively lower cost. A specific thermoplastic resin is used as the adhesive layer-forming resin in the back sheet, or a surface treatment layer is provided on the adhesive layer to improve the adhesion for the sealing material, and the porosity of the adhesive layer is controlled within a predetermined range to maintain strength as the solar-cell back sheet.

Further, the solar-cell back sheet of the present invention hardly undergoes discoloration under short-wavelength light (ultraviolet rays) as compared with a back sheet that uses a polyester film, and exhibits stable performance without greatly lowering reflectance even after long use.

### BRIEF DESCRIPTION OF THE DRAWINGS

FIG. 1 is a cross sectional view representing an embodiment of a solar-cell back sheet of the present invention.

FIG. 2 is a cross sectional view representing an embodiment of a solar cell of the present invention.

FIG. 3 is a graph representing the correlation between the reflectance of the solar-cell back sheets of Examples and Comparative Example of the present invention, and the maximum output (Pmax) of solar cells that use the solar-cell back sheets.

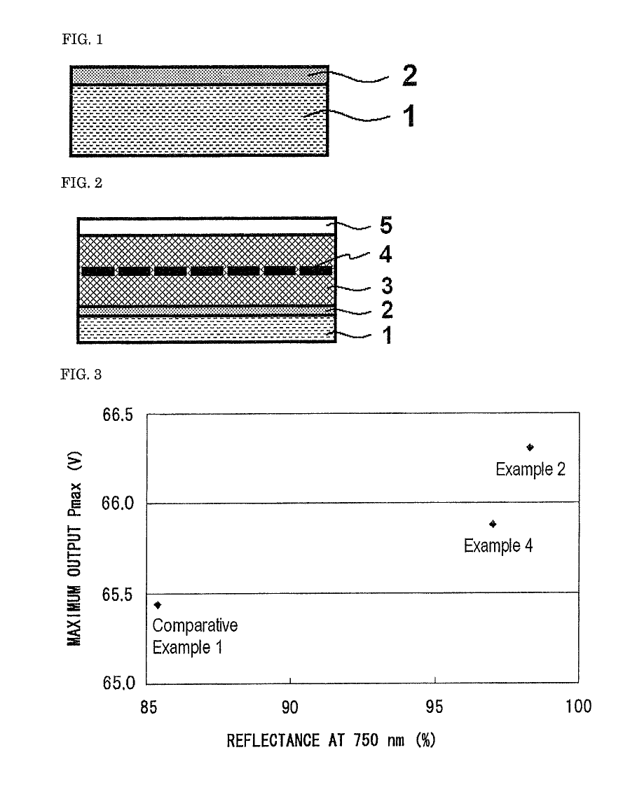

### MODE FOR CARRYING OUT THE INVENTION

The configuration and the advantages of the solar-cell back sheet of the present invention are described below in detail. The descriptions of the constituting elements below, including the representative embodiments thereof according to the present invention, serve solely to illustrate the present invention, and the present invention is not limited by such embodiments. As used herein, the numerical ranges defined with “to” are intended to be inclusive of the numbers specified by “to” as the lower limit and the upper limit.

### <Solar-Cell Back Sheet>

The solar-cell back sheet of the present invention is formed of a laminate of at least a base layer and an adhesive layer. The laminate has a reflectance of 90% or more for light of 750 nm wavelength as measured according to the method described under condition d of JIS-Z8722, and a partial discharge voltage of 7.5 V or more per micrometer of laminate thickness as measured according to the method described in IEC-60664-1.

The following specifically describes the present invention by referring to the preferred embodiment of the solar-cell back sheet of the present invention.

### <Base Layer>

The base layer in the solar-cell back sheet of the present invention is formed of a polypropylene-based resin film having holes inside, and represents a major layer that imparts high reflectance and high voltage resistance to the back sheet.

The base layer contains 30 to 95% by weight of polypropylene resin, and 5 to 70% by weight of at least one of an inorganic filler and an organic filler, and is stretched in at least one direction, and has a porosity of 55% or less.

By being formed of a nonpolar polypropylene resin, the base layer can impart sufficiently high partial discharge voltage by itself. Further, by containing the filler and forming specific numbers of holes within the layer, the base layer can achieve sufficiently high reflectance by itself.

### <Polypropylene Resin>

The polypropylene resin may be a propylene homopolymer, or a copolymer of a main component propylene, and α-olefins such as ethylene, 1-butene, 1-hexene, 1-heptene, and 4-methyl-1-pentene. The tacticity is not particularly limited, and the polypropylene resin may exhibit various levels of tacticity, including isotacticity, and syndiotacticity. The copolymer may be of two, three, or four monomeric species, or a random copolymer or a block copolymer. A propylene homopolymer is preferred from the standpoint of hole formation.

The dielectric constant of the polypropylene resin is 2.2 to 2.6. The dielectric constant of polyethylene terephthalate resin is 2.9 to 3. The dielectric constant of air is about 1. Use of the nonpolar polypropylene resin, and hole formation are thus advantageous for improving insulation resistance.

The base layer contains the polypropylene resin in 30 to 95% by weight, preferably 35% by weight or more, more preferably 40% by weight or more in this range. The content is preferably 90% by weight or less, more preferably 85% by weight or less. When the polypropylene resin content in the base layer is 30% by weight or more, the dielectric constant of the back sheet tends to remain low, and the mechanical strength is unlikely to suffer. At or below 95% by weight, sufficient numbers of holes can be obtained, and the reflectance tends to increase.

### <Inorganic Filler>

The base layer contains the filler as a nucleating agent that forms holes inside the layer.

Examples of the inorganic filler include heavy calcium carbonate, precipitated calcium carbonate, calcined clay, talc, titanium oxide, barium sulfate, aluminum sulfate, silica, zinc oxide, magnesium oxide, and diatomaceous earth. These inorganic fillers may be surface treated with various surface treatment agents. It is preferable to use heavy calcium carbonate, precipitated calcium carbonate, surface treated products thereof, clay, and diatomaceous earth, because these materials are inexpensive, and help form holes during the stretching. It is further preferable to use heavy calcium carbonate, and precipitated calcium carbonate after surface treatment with various surface treatment agents. Titanium oxide is preferred for use as the inorganic filler because titanium oxide has high refractive index, and can achieve high reflectance regardless of whether holes are formed.

Preferred examples of the surface treatment agents include resin acids, fatty acids, organic acids, sulfate anion surfactants, sulfonate anion surfactants, petroleum resin acids, and sodium, potassium, and ammonium salts thereof, or fatty acid esters and resin acid esters thereof, waxes, and paraffins. Other preferred examples include non-ionic surfactants, diene polymers, titanate coupling agents, silane coupling agents, and phosphate coupling agents. Examples of the sulfate anion surfactants include long-chain alcohol sulfuric acid ester, polyoxyethylene alkyl ether sulfuric acid ester, sulfated oil, and sodium and potassium salts thereof. Examples of the sulfonate anion surfactants include alkylbenzenesulfonic acid, alkylnaphthalene sulfonic acid, paraffin sulfonic acid, α-olefin sulfonic acid, alkylsulfosuccinic acid, and sodium and potassium salts thereof. Examples of the fatty acids include caproic acid, caprylic acid, pelargonic acid, capric acid, undecanoic acid, lauric acid, myristic acid, palmitic acid, stearic acid, hebenic acid, oleic acid, linoleic acid, linolenic acid, and eleostearic acid. Examples of the organic acids include maleic acid, and sorbic acid. Examples of the diene polymers include polybutadiene, and isoprene. Examples of the non-ionic surfactants include polyethylene glycol ester surfactants. These surface treatment agents may be used either alone or in a combination of two or more. The surface treatment of the inorganic filler with these surface treatment agents may be performed by using the methods described in, for example, JP-A-5-43815, JP-A-5-139728, JP-A-7-300568, JP-A-10-176079, JP-A-11-256144, JP-A-11-349846, JP-A-2001-158863, JP-A-2002-220547, and JP-A-2002-363443.

### <Organic Filler>

A resin having a higher melting point or glass transition point (for example, 120 to 300° C.) than the melting point of the polypropylene resin forming the base layer may preferably be used as the organic filler. Specific examples include polyethylene terephthalate, polybutylene terephthalate, polyamide, polycarbonate, polyethylene naphthalate, polystyrene, melamine resin, cyclic olefin copolymer, polyethylene sulfide, polyimide, polyethyl ether ketone, and polyphenylene sulfide. These are incompatible to the polypropylene resin, and are preferred for desirable hole formation during stretching.

The inorganic filler or the organic filler may be selected and used alone for the base layer. Alternatively, two or more inorganic fillers and organic fillers may be selected, and used in combination. When two or more inorganic fillers and organic fillers are used, the organic filler and the inorganic filler may be used in combination.

The base layer contains the inorganic filler and/or the organic filler in 5 to 70% by weight, preferably 10% by weight or more, more preferably 15% by weight or more in this range. The content is preferably 65% by weight or less, more preferably 60% by weight or less. When the filler content in the base layer is 5% by weight or more, sufficient numbers of holes can be obtained, and the reflectance tends to increase. At or below 70% by weight, the mechanical strength of the back sheet is unlikely to suffer, and the dielectric constant of the back sheet tends to remain low.

### <Filler Particle Size>

The average particle diameter of the inorganic filler, and the average dispersion particle diameter of the organic filler may be determined by using, for example, a micro-tracking method, observation of primary particle size with a scanning electron microscope (the mean value of 100 particles are used as the average particle diameter in the present invention), or conversion from a specific surface area (specific surface area is measured with a powder specific surface area measurement device SS-100 (Shimadzu Corporation) in the present invention).

In order to control the size of the holes formed by stretch molding in base layer production (described later), it is preferable that the inorganic filler added to the base layer have a specific average particle diameter, or that the average dispersion particle diameter of the organic filler be controlled by kneading.

The wavelengths that contribute to the power efficiency of the voltaic elements in the solar cell are wavelengths in the visible to near-infrared region, and, desirably, the back sheet effectively reflects light of the wavelengths in the visible to near-infrared region.

To this end, the average particle diameter or the average dispersion particle diameter of the filler contained in the base layer is preferably 0.05 μm or more, more preferably 0.1 μm or more, further preferably 0.15 μm or more, and preferably 0.9 μm or less, more preferably 0.5 μm or less, further preferably 0.4 μm or less.

When the average particle diameter or the average dispersion particle diameter of the filler contained in the base layer is 0.05 to 0.9 μm, holes of moderate sizes are formed, and the reflectance of light in the visible light to near-infrared region tends to improve.

A mixture of more than one filler may be used in the base layer. In this case, the proportion of the filler with an average particle diameter or an average dispersion particle diameter of 0.05 to 0.9 μm is preferably 50% or more, more preferably 75% or more, further preferably 90% or more, even more preferably 100% of the all fillers.

### <Other Components>

The main resin component of the base layer is polypropylene resin. However, for improved ease of stretch, a resin, such as polyethylene, ethylene-vinyl acetate copolymer, cyclic olefin homopolymer, and cyclic olefin copolymer, having a lower melting point than the melting point of the polypropylene resin may be mixed in the base layer in, for example, 1 to 25% by weight of the total base layer. Such low-melting-point resins are mixed preferably in 2% by weight or more, more preferably 3% by weight or more of the total base layer, and preferably 22% by weight or less, more preferably 20% by weight or less.

Other additives, such as a heat stabilizer (antioxidant), a light stabilizer, a dispersant, a fluorescent bleach, and a lubricant may be mixed in the base layer, as required. The heat stabilizer may be of sterically hindered phenol, phosphorus, or amine, and may be mixed in, for example, 0.001 to 1% by weight. The light stabilizer may be of sterically hindered amine, benzotriazole, or benzophenone, and may be mixed in, for example, 0.001 to 1% by weight. The inorganic filler dispersant may be a silane coupling agent, higher fatty acids such as oleic acid and stearic acid, metallic soap, polyacrylic acid, polymethacrylic acid, or a salt thereof, and may be mixed in, for example, 0.01 to 4% by weight. The organic filler dispersant may be a modified polyolefin such as maleic acid modified-polypropylene, and silanol modified-polypropylene, and may be mixed in, for example, 0.01 to 4% by weight.

### <Producing Process>

The base layer is stretched in at least one direction to form inner holes using the filler as a nucleus. In order to reduce the direction dependence of reflectance, the base layer is preferably biaxially stretched in longitudinal and transverse directions.

Common uniaxial and biaxial stretching may be used as the methods of stretching. In one specific example of such methods, a resin composition melt is extruded into a form of a sheet through a single-layer or multilayer T die or I die connected to a screw-type extruder, and uniaxially stretched in the longitudinal direction by using the circumferential velocity difference of the group of rollers. Other examples include a biaxial stretching method that uses a tenter oven and performs transverse stretching after the uniaxial stretching performed as above, and a simultaneous biaxial stretching method that uses a tenter oven and a linear motor, or a tenter oven and a pantograph in combination. As used herein, “longitudinal stretch” means stretching in MD (machine direction), and “transverse stretch” means stretching in the sheet width direction orthogonal to MD.

The base layer used in the present invention is not limited to a monolayer structure, and may have a multilayer structure of two or more layers.

The base layer having a multilayer structure may be produced by using a method in which the raw material melt of each resin composition is coextruded with a multilayer T die or I die. A method that laminates layers with multiple dies, and a method that laminates individually produced films by using a technique such as dry lamination also may be used. The resulting laminate may be further stretched and molded. As an example, when the base layer has a multilayer structure of a surface layer, a support layer, and a surface layer, all of these layers may be uniaxially or biaxially stretched, or each layer may be stretched in different directions, such as in a uniaxial/biaxial/uniaxial combination.

When the base layer is a biaxially stretched layer, all of the layers may be biaxial stretched after being laminated, or a raw material melt of surface layers may be extruded onto the both surfaces of a supporting layer after this layer is uniaxial stretched (for example, longitudinally), and the resulting multilayer structure may be stretched in a different direction (for example, transversely) to produce a base layer that is biaxially stretched only in the supporting layer.

In order to have the desired size for the holes formed in the base layer, it is preferable that the area stretch rate in the stretching step be 1.3 times or more, more preferably 7 times or more, further preferably 22 times or more, particularly preferably 25 times or more, and preferably 80 times or less, more preferably 70 times or less, further preferably 65 times or less, particularly preferably 60 times or less, in addition to setting the filler particle size as above. With an area stretch rate confined in the 1.3 to 80 times range, it becomes easier to form finer holes, and the reflectance is less likely to decrease. As used herein, “area stretch rate” is the rate represented by longitudinal stretch rate×transverse stretch rate.

### <Porosity>

The number of holes formed in the resin layer may be represented in terms of porosity. The porosity of the base layer is preferably 0% or more, more preferably 3% or more, further preferably 7% or more, particularly preferably 20% or more, and preferably 55% or less, more preferably 53% or less, further preferably 50% or less, particularly preferably 45% or less. For example, the porosity of the base layer may be adjusted in a range of 3 to 53%, or 25 to 53%.

When the porosity is 0% or more, the partial discharge voltage tends to increase, and the reflectance also tends to increase when the porosity is 20% or more. A porosity of 55% or less makes it easier to prevent the mechanical strength of the back sheet from being lowered, and cohesion failure between the adhesive layer and the base layer of the laminate is less likely to occur when the sealing material bonded to the base layer is detached. This further improves the adhesion for the sealing material.

### <Thickness>

The thickness of the base layer should be as thick as possible for improved performance of the solar-cell back sheet of the present invention, including reflectance, partial discharge voltage, water vapor permeability, and dimension stability. However, the thickness of the base layer is preferably 70 μm or more, more preferably 75 μm or more, further preferably 80 μm or more, particularly preferably 90 μm or more, and preferably 250 μm or less, more preferably 230 μm or less, further preferably 215 μm or less, particularly preferably 200 or less. The foregoing performance of the base layer does not suffer when the base layer has a thickness of 70 μm or more, and the base layer can be expected to be more cost effective than conventional products when the thickness is 250 μm or less.

### <Adhesive Layer>

The adhesive layer in the solar-cell back sheet of the present invention is a layer in contact with the sealing material side of the solar cell module, and has a surface that strongly adheres to the sealing material of the solar cell module to prevent detachment at the interface between the solar-cell back sheet and the sealing material.

The adhesive layer contains 50 to 100% by weight of thermoplastic resin, and 0 to 50% by weight of at least one of the inorganic filler and the organic filler, and has a porosity of 0 to 3%.

Because the adhesive layer is almost completely devoid of holes inside, the adhesive layer does not undergo material failure, and can reduce gas permeation. The adhesive layer can have improved adhesion for the sealing material when a preferably specific thermoplastic resin is used, or a surface treatment layer is provided.

### <Thermoplastic Resin>

A polyolefin-based resin is preferably used as the thermoplastic resin of the adhesive layer. Using a polyolefin-based resin can improve partial discharge voltage because of the low dielectric constant as with the case of the base layer, and is less likely to cause discoloration in the laminate under ultraviolet light, and lowering of reflectance even after long use.

Examples of the polyolefin-based resin include polyethylene-based resins (such as high-density polyethylene, medium-density polyethylene, and low-density polyethylene), ethylene-vinyl acetate copolymer resin, propylene-based resin, polymethyl-1-pentene, cyclic olefin homopolymer, and ethylene-cyclic olefin copolymer.

The propylene-based resin may be a propylene homopolymer, or a copolymer of a main component propylene and α-olefins such as ethylene, 1-butene, 1-hexene, 1-heptene, 1-octene, and 4-methyl-1-pentene. The tacticity is not particularly limited, and the propylene resin may exhibit various levels of tacticity, including isotacticity, and syndiotacticity. The copolymer may be of two, three, or four monomeric species. For imparting a heat sealing property in the production of the solar cell module, the propylene-based resin is preferably a low-melting-point propylene-based resin such as a random copolymer and a block copolymer.

The sealing material of the solar cell module is typically ethylene-vinyl acetate copolymer resin. From the standpoint of adhesion, the polyolefin-based resin used for the adhesive layer is preferably a polyethylene-based resin having a melting point of less than 150° C., an ethylene-vinyl acetate copolymer having a melting point of less than 150° C., or a random copolymer of propylene-based resin having a melting point of less than 150° C., because these materials can be bonded to the sealing material by thermofusion.

High adhesion for the sealing material can be achieved even when a high-melting-point polypropylene resin (melting point of 150° C. or more) is used as the thermoplastic resin, provided that the adhesive layer surface is subjected to an activation process such as corona discharge, or coated with a surface treatment layer of primarily acrylic acid ester-based resin or polyethyleneimine-based resin. Further, a high-melting-point polypropylene resin may be used in combination with two or more of low-melting-point polypropylene resins, and adhesion improvers such as maleic acid modified-polypropylene to adjust adhesion strength.

Preferably, the back sheet of the present invention is configured to include the adhesive layer as the outermost layer so as to allow the adhesive layer to directly contact the sealant of the solar cell module, or include the surface treatment layer as the outermost layer on the adhesive layer so that the adhesive layer can contact the sealant of the solar cell module via the surface treatment layer. When the surface treatment layer is provided as in the latter, the solid content in the surface treatment layer is preferably 0.005 g or more, more preferably 0.01 g or more per 1 m², and preferably 0.5 g or less, more preferably 0.1 g or less per 1 m².

The adhesive layer contains 50 to 100% by weight of thermoplastic resin. The content is preferably 70% by weight or more, more preferably 97% by weight or more, particularly preferably substantially 100% by weight in this range. When the thermoplastic resin content in the adhesive layer is 50% by weight or more, the mechanical strength of the adhesive layer is less likely to suffer, and the adhesion is less likely to decrease.

The adhesive layer may contain at least one of an inorganic filler and an organic filler to increase the surface roughness and improve the fitting and adhesion for the sealing material, or to help facilitate air release during the heat press performed for bonding the sealing material. The fillers are contained in 0 to 50% by weight in the adhesive layer. The content is preferably 30% by weight or less, more preferably 3% by weight or less, particularly preferably substantially 0% in this range. When the filler content in the adhesive layer is 50% by weight or less, the mechanical strength of the adhesive layer is less likely to suffer, and the adhesion is less likely to decrease.

### <Inorganic Filler and Organic Filler>

The same inorganic fillers and organic fillers used for the base layer may be used for the adhesive layer.

### <Other Components>

As to other adhesive layer components, the adhesive layer may contain the same components used for the base layer.

### <Producing Process>

The adhesive layer may be formed by using the same stretch method used for the base layer. However, because holes are not necessarily required, the adhesive layer may be an unstretched resin sheet. In this case, a hot melt of a resin composition of the adhesive layer may be laminated on the molded base layer by extrusion lamination.

### <Porosity>

The porosity of the adhesive layer is preferably 0% or more, and preferably 3% or less, more preferably 2% or less, further preferably 1% or less. Particularly preferably, the adhesive layer does not contain substantially any hole. A low-porosity adhesive layer can be realized by reducing the content of the filler mixed in the adhesive layer, or by molding the adhesive layer without stretching. A low-porosity adhesive layer also can be realized even when the adhesive layer is stretched. This can be achieved by using a low-melting-point thermoplastic resin, and melting the resin before stretching and molding, or by stretching the resin along fewer axes or at lower stretch rate. With a porosity of 3% or less, the adhesive layer does not undergo material failure, and can further reduce gas permeation.

### <Thickness>

The thickness of the adhesive layer is preferably 0.5 or more, more preferably 1 μm or more, further preferably 5 μm or more, particularly preferably 8 μm or more, and preferably 50 μm or less, more preferably 40 μm or less, further preferably 35 μm or less, particularly preferably 30 μm or less. Adhesion tends to become sufficient when the adhesive layer has a thickness of 0.5 μm or more. A thickness of 50 μm or less tends to provide good moldability, and improve the cost effectiveness.

### <Lamination>

The solar-cell back sheet of the present invention is formed of a laminate of at least the base layer and the adhesive layer. In one exemplary method of obtaining a laminate of these layers, a resin composition of each layer is melt kneaded with an extruder, and laminated in a multilayer T die or I die. The molten raw materials are then coextruded, and the resulting sheet-like material is cooled on a cooling roller to solidify. In another exemplary method, the base layer is formed into a form of a sheet, and a resin composition of the adhesive layer is melt kneaded with an extruder. The melt is then extruded with a T die or the like, melt laminated on the base layer, and cooled on a cooling roller to solidify.

### <Laminate>

### <Laminate Performance>

The laminate as the solar-cell back sheet of the present invention has a reflectance of 90% or more at 750 nm wavelength as measured according to the method described in condition d of JIS-Z8722, and a partial discharge voltage of 7.5 V or more per micrometer of laminate thickness as measured according to the method described in IEC-60664-1.

### <Reflectance>

The solar-cell back sheet of the present invention has a reflectance of 90% or more as measured at the light reflecting surface (the surface on the adhesive layer side) by using the method below. The reflectance is preferably 93% or more, more preferably 95% or more, further preferably 97% or more, and preferably 120% or less, more preferably 110% or less, further preferably 100% or less. When the reflectance is below 90%, the incident light on the solar cell module cannot be effectively reflected and reused to efficiently improve the power exchange efficiency of the solar cell.

The high reflectance of the solar-cell back sheet of the present invention is realized by the holes formed in the laminate, particularly the base layer. The reflectance is essentially porosity dependent, and tends to increase as the porosity increases. In the present invention, however, the porosity range is specified taking into account the mechanical strength of the back sheet, and the adhesion for the sealing material.

It is believed from the wavelength absorption characteristics of photovoltaic elements that solar cell power efficiency is contributed particularly by visible light to near-infrared light.

Studies by the present inventors have found that the holes formed in the base layer can effectively reflect light. The hole size is an important factor, because it contributes to increase and decrease of the reflectance of light of specific wavelengths.

The hole size can be confined in a specific range by the average particle diameter of the inorganic filler, and the average dispersion particle diameter of the organic filler contained in the polypropylene resin. Specifically, with a filler having a particle size of 0.05 to 0.9 μm, it becomes easier to more effectively reflect visible light to near-infrared light.

It has been confirmed that a solar-cell back sheet having a reflectance as high as 98% in this wavelength range can be obtained with the laminate of the present invention, and that the maximum output can be improved by about 1.5% compared to a solar-cell back sheet that uses a conventional polyester film and has a reflectance of about 85% (see FIG. 3). The maximum output (Pmax) is the optimum operating point of an I-V curve obtained by connecting the open-circuit voltage value and the short-circuit current value of the module.

### <Partial Discharge Voltage>

The solar-cell back sheet is required to withstand a partial discharge voltage of 700 V or more, or 1,000V or more, depending on the power capacity of the photovoltaic element cells installed in the solar cell module. On the other hand, it is common knowledge that the partial discharge voltage of a polymer film is dependent on the film thickness. Aback sheet that uses a polyester film for improved voltage resistance performance thus tends to have a large thickness, adding to the cost. Partial discharge voltage may be measured by using the method below.

The solar-cell back sheet of the present invention has a partial discharge voltage of 7.5 V or more per micrometer of thickness. The partial discharge voltage per thickness is preferably 8 V/μm or more, more preferably 9 V/μm or more, and preferably 15 V/μm or less, more preferably 13 V/μm or less. When the partial discharge voltage per thickness is 7.5 V/μm or more, the solar-cell back sheet (particularly the base layer) may have a thickness of 93 μm or more, or 133 μm or more, as may be decided according to the required levels, and sufficient partial discharge voltage resistance can be obtained even with a film thinner than, for example, the polyester films of the foregoing Cited Documents 2 and 3. This makes it possible to reduce cost.

### <Adhesion for Sealing Material>

An ethylene-vinyl acetate copolymer resin is typically used as the sealing material of the solar cell module, as described above. For preventing lowering of solar cell performance, the adhesion between the sealing material and the solar-cell back sheet should be as high as possible. In the present invention, adhesion is improved, for example, by using the technique whereby a low-melting-point thermoplastic resin is used for the adhesive layer to join these materials by thermofusion, as described above. Specifically, the resulting adhesion for the sealing material of the back sheet is preferably 20 N/25 mm or more, more preferably 50 N/25 mm or more, further preferably 70 N/25 mm or more in terms of a peel force between the solar cell module and the back sheet as measured according to the method described in JIS-K6854-2. The effect of improving the adhesion for the sealing material becomes poor when the peel force is less than 20 N/25 mm.

### <Reducing the Rate of Thermal Shrinkage>

Bonding of the back sheet to the solar cell module is typically performed by heat compression at 150° C. for 30 min. The back sheet is thus expected to have a low rate of thermal shrinkage. The rate of thermal shrinkage of the back sheet can be reduced by, for example, subjecting the laminate to chamber treatment, or performing a heat treatment (annealing) during the production step.

### <Configuration of Laminate Layer>

The laminate forming the solar-cell back sheet of the present invention having at least two layers, the adhesive layer and the base layer, may be configured from more than two layers, in addition to these layers. In this case, for example, an outermost layer, such as a protective layer, may be provided on one of the top and bottom surfaces or the both surfaces of the laminate, in addition to the adhesive layer and the base layer. An interlayer, such as a function imparting layer, also may be additionally provided, as required. The protective layer is, for example, a resin film that includes at least one of polyester-based resin and fluororesin, and is provided to improve mechanical strength, heat resistance, moisture resistance, and weather resistance. The function imparting layer is, for example, a gas barrier film, a light shield film, a shielding layer, a metallization film, or an aluminum foil as described in Patent Document 2, and is provided to improve the gas barrier or shielding property of the solar-cell back sheet.

Specifically, the laminate may be structured to include a protective layer laminated on the opposite surface of the base layer surface in contact with the adhesive layer, or a function imparting layer laminated between the adhesive layer and the base layer, or between the base layer and the protective layer. Two or more function imparting layers may be provided. The thermoplastic resin, the filler, the additive, and other materials used for the protective layer and the function imparting layer may be selected from the wide range of the materials described above, provided that such materials do not affect the advantages of the present invention. Specifically, for example, the solar-cell back sheet of the present invention preferably has the following layer configurations.

Adhesive layer/base layer,

Adhesive layer/base layer/protective layer

Adhesive layer/function imparting layer/base layer

Adhesive layer/function imparting layer/base layer/protective layer

Adhesive layer/base layer/function imparting layer/protective layer

Adhesive layer/function imparting layer/base layer/function imparting layer/protective layer

### EXAMPLES

The present invention is described below in greater detail using Examples, Comparative Examples, and Test Examples. The materials, amounts, proportions, procedures, and other conditions used in the following Examples may be appropriately varied, provided that such changes do not depart from the gist of the present invention. Accordingly, the scope of the present invention should not be narrowly interpreted within the limits of the concrete examples described below.

### Examples 1, 2, 6, 10, and 11

Composition (B) containing the materials of Table 1 at the mixture ratio of Table 2 was melt kneaded at 250° C. with an extruder. The kneaded product was extruded into a form of a sheet, and cooled to about 60° C. with a cooling roller to obtain a thermoplastic resin sheet. After being re-heated to 145° C., the thermoplastic resin sheet was longitudinally stretched at the rate presented in Table 2 by using the circumferential velocity difference of a group of multiple rollers.

Subsequently, composition (A) using the materials of Table 1 under the conditions presented in Table 2 was melt kneaded at 250° C. with a different extruder, and melt extruded onto one surface of the thermoplastic resin sheet above to obtain a laminate of an (A)/(B) structure.

After being re-heated to 160° C., the laminate was transversely stretched at the rate presented in Table 2, using a tenter. After being annealed at 165° C., the laminate was cooled to 60° C., and the ear portions were slit to obtain a laminate of a two-layer structure (adhesive layer (A)/base layer (B)) having the thickness presented in Table 2.

The laminate were subjected to a corona discharge on the both sides, and an aqueous solution containing 0.5% by weight (solid content) of a polyethyleneimine-based resin adhesion improver (product name: Polymin SK; BASF Japan) was applied to the both surfaces of the laminate in a manner that makes the dry solid content 0.01 g per 1 m². The laminate obtained after drying had surface treatment layers on the both sides, and was used as a solar-cell back sheet.

### Example 3

Composition (B) containing the materials of Table 1 at the mixture ratio of Table 2 was melt kneaded at 250° C. with an extruder. The kneaded product was extruded into a form of a sheet, and cooled to about 60° C. with a cooling roller to obtain a thermoplastic resin sheet. After being re-heated to 145° C., the thermoplastic resin sheet was longitudinally stretched at the rate presented in Table 2 by using the circumferential velocity difference of a group of multiple rollers.

Composition (A) using the PP1 of Table 1 was then melt kneaded at 250° C. with a different extruder, and melt extruded onto one surface of the thermoplastic resin sheet above to obtain a laminate of an (A)/(B) composition. The laminate was passed between a rubber roller and a metallic embossing roller (150 lines per inch, a gravure (inverted pyramid) type) to emboss continuous pyramid-shape patterns (0.17 mm intervals, 15 μm deep) on the surface of the adhesive layer formed by composition (A).

After being re-heated to 160° C., the laminate was transversely stretched at the rate presented in Table 2, using a tenter. After being annealed at 165° C., the laminate was cooled to 60° C., and the ear portions were slit to obtain a laminate of a two-layer structure (adhesive layer (A)/base layer (B)) having the thickness presented in Table 2.

The laminate was subjected to a corona discharge on the both sides, and an aqueous solution containing 0.5% by weight (solid content) of a polyethyleneimine resin adhesion improver (product name: Polymin SK; BASF Japan) was applied to the both surfaces of the laminate in a manner that makes the dry solid content 0.01 g per 1 m². The laminate obtained after drying had surface treatment layers on the both sides, and was used as a solar-cell back sheet.

### Examples 4 and 5

Laminates were obtained in the same manner as in Example 1, except that composition (A) of Table 2 was used to form the adhesive layer (A), and was stretched at the rate presented in Table 2, and that the surface treatment by a corona discharge and the surface treatment layer formation were not performed. The laminates were used as solar-cell back sheets.

### Example 7

Composition (B) containing the materials of Table 1 at the mixture ratio of Table 2 was melt kneaded at 250° C. with an extruder. The kneaded product was extruded into a form of a sheet, and cooled to about 60° C. with a cooling roller to obtain a thermoplastic resin sheet. After being re-heated to 145° C., the thermoplastic resin sheet was longitudinally stretched at the rate presented in Table 2 by using the circumferential velocity difference of a group of multiple rollers.

Subsequently, composition (A) containing the materials of Table 1 at the mixture ratio presented in Table 2 was melt kneaded at 250° C. with a different extruder, and melt extruded onto a surface of the thermoplastic resin sheet above to obtain a laminate of an (A)/(B) structure.

After being re-heated to 160° C., the laminate was transversely stretched at the rate presented in Table 2, using a tenter. After being annealed at 165° C., the laminate was cooled to 60° C., and the ear portions were slit to obtain a laminate of a two-layer structure (adhesive layer (A)/base layer (B)) having the thickness presented in Table 2.

The laminate was subjected to a corona discharge on the both sides, and an aqueous solution containing 0.5% by weight (solid content) of a polyethyleneimine resin adhesion improver (product name: Polymin SK; BASF Japan) was applied to the both surfaces of the laminate in a manner that makes the dry solid content 0.01 g per 1 m². The laminate obtained after drying had surface treatment layers on the both sides.

A transparent polyester film (product name: Diafoil O300E; Mitsubishi Plastics; thickness 100 μm) was then laminated as protective layer (C) on the base layer (B) side of the laminate by using a dry lamination method to obtain an (A)/(B)/(C) laminate. The laminate was used as a solar-cell back sheet.

### Examples 8 and 9

Composition (B) containing the materials of Table 1 at the mixture ratio of Table 2 was melt kneaded at 250° C. with an extruder. The kneaded product was extruded into a form of a sheet, and cooled to about 60° C. with a cooling roller to obtain a thermoplastic resin sheet. After being re-heated to 145° C., the thermoplastic resin sheet was longitudinally stretched at the rate presented in Table 2 by using the circumferential velocity difference of a group of multiple rollers.

Subsequently, composition (A) containing the materials of Table 1 at the mixture ratio presented in Table 2 was melt kneaded at 250° C. with a different extruder, and melt extruded onto a surface of the thermoplastic resin sheet above to obtain a laminate of an (A)/(B) structure.

After being re-heated to 160° C., the laminate was transversely stretched at the rate presented in Table 2, using a tenter. After being annealed at 165° C., the laminate was cooled to 60° C., and the ear portions were slit to obtain a laminate of a two-layer structure (adhesive layer (A)/base layer (B)) having the thickness presented in Table 2.

The laminate was subjected to a corona discharge on the both sides, and an aqueous solution containing 0.5% by weight (solid content) of a polyethyleneimine resin adhesion improver (product name: Polymin SK; BASF Japan) was applied to the both surfaces of the laminate in a manner that makes the dry solid content 0.01 g per 1 m². The laminate obtained after drying had surface treatment layers on the both sides.

A gas barrier film (product name: Techbarrier HX; Mitsubishi Plastics; thickness 12 μm), and a transparent polyester film (product name: Diafoil T600E; Mitsubishi Plastics; thickness 50 μm) were then laminated as function imparting layer (D) and protective layer (C), respectively, on the base layer (B) side of the laminate by using a dry lamination method to obtain an (A)/(B)/(D)/(C) laminate. The laminate was used as a solar-cell back sheet.

### Comparative Example 1

A white polyester film (product name: E20; thickness: 100 μm; Toray) commonly used as a back sheet was obtained, and used as a solar-cell back sheet.

### Comparative Example 2

A laminate was obtained in the same manner as in Example 1, except that composition (A) containing the materials of Table 1 in the mixture ratio of Table 2 was used. The laminate was used as a solar-cell back sheet. The adhesive layer (A) of the back sheet had a porosity of 6%.

### Comparative Example 3

A laminate was obtained in the same manner as in Example 1, except that the stretch rates presented in Table 2 were used, and that the base layer (B) had the thickness shown in Table 2. The laminate was used as a solar-cell back sheet. The base layer (B) of the back sheet had a porosity of 18%.

### Comparative Example 4

A laminate was obtained in the same manner as in Example 1, except that the stretch rates presented in Table 2 were used. The laminate was used as a solar-cell back sheet. The base layer (B) of the back sheet had a porosity of 56%.

### Test Example

### Reflectance

The solar-cell back sheets obtained in Examples and Comparative Examples were measured for reflectance at the surface on the light reflecting side (the adhesive layer (A) side) at 750 nm wavelength according to the method described in condition d of JIS-Z8722, using a spectrophotometer (product name: U-3310; Hitachi) equipped with an integrating sphere of 150 mm diameter. The measurement result was used to calculate a relative reflectance with respect to 100% reflectance obtained under the same conditions with a standard aluminum oxide plate equipped in the measurement device.

### <Thickness>

The solar-cell back sheets obtained in Examples and Comparative Examples were measured for total thickness according to the method described in JIS-P8118, using a thickness meter (HyBridge Co., Ltd.).

The thickness of each layer in the solar-cell back sheet was calculated from the thickness proportion of each layer with respect to the total thickness determined above. The thickness proportion was determined from the appearance of the interface between the layers by observing a cross section of each laminate with an electron microscope in the porosity observation described below.

### <Partial Discharge Voltage>

The whole thickness partial discharge voltage of the solar-cell back sheets obtained in Examples and Comparative Examples was measured according to the method described in IEC 60664-1, using a partial discharge tester (product name: Partial Discharge System DAC-6031, Soken Electric Co., Ltd.).

### <Peel Force>

Pellets of an ethylene-vinyl acetate copolymer (product name: Evaflex EV45X, Mitsui-Du Pont Chemicals) were heat pressed and molded into a form of a plate shape having a thickness of about 400 μm. This was used as a pseudo-sealing material of a solar cell module.

Each solar-cell back sheet obtained in Examples and Comparative Examples was cut into an A4 size sheet. Two sheets of each sample were disposed face to face on the side of the adhesive layer, and laminated in such a manner that the adhesive layer of each back sheet was in contact with the sealing material interposed between the sheets.

The laminate was placed between two SUS plates, and heated under applied pressure with a heat press (150° C., 10 MPa/cm² pressure, 30 min) to press bond the back sheets to the sealing material and obtain a pseudo-solar cell sample. After being cooled, the sample was cut into a 25 mm width, and one of the back sheets, and the sealing material of the sample were partly peeled by hand with care to form gripping portions (tabs). The resulting sample was used as a test piece.

Each test piece was stored in a constant temperature room (temperature 20° C., relative humidity 65%) for one week, and the back sheet and the sealing material were peeled by pulling the gripping portions at a rate of 200 mm/min according to the method described in JIS K6854-2, using a tensile tester (product name: Autograph AGS-5KND; Shimadzu Corporation). The back sheet and the sealing material were peeled 180° over a distance of at least 100 mm, and the stress exerted while the peeling was stable was measured with a load cell.

The measurement was performed three times along the longitudinal (lengthwise) and transverse (width) directions of each laminate, and the mean value was taken as a peel force. The peel force was used as a measure of the adhesion between the sealing material and the back sheet.

### <Porosity>

The porosity in each layer of the solar-cell back sheet of the present invention was measured by observing the holes in each layer. Specifically, the holes of the laminate were cut while cooling the holes to prevent a crush. The sample with the exposed cross section (observation surface) along the thickness was attached to a sample observation stage, and gold was deposited on the observation surface for observation with a scanning electron microscope (SM-200; TOPCON) at the desired magnifications (500 to 3,000 times). The observed region was incorporated as image data, and the image was processed with an image analyzer (Luzex AP; Nireco Corporation) to find the percentage of the hole area. This percentage was obtained as the porosity.

TABLE 1

| | Abbre- | |
|---|---|---|
| Type | viation | Content |
| Polypropylene | PP1 | Propylene homopolymer (product name: Novatec PP FY6C; Japan Polypropylene Corporation; MFR (230° C., 2.16 kg load): |
| resin | | 2.4 g/10 min., melting point (DSC peak temperature): 167° C.) |
| Thermoplastic | PP2 | Propylene random copolymer (product name: Novatec PP FW4BT; Japan Polypropylene Corporation; MFR (230° C., 2.16 kg |
| resin | | load): 4 g/10 min., melting point (DSC peak temperature): 142° C.) |
| | HDPE | High-density polyethylene (product name: Novatec HD HJ360; Japan Polyethylene Corporation; MFR (190° C., 2.16 kg |
| | | load): 5.5 g/10 min., melting point (DSC peak temperature): 134° C.) |
| | EVA | Ethylene-vinyl acetate copolymer (product name: Novatec EVA LV342; Japan Polyethylene Corporation; MFR (190° C., |
| | | 2.16 kg load): 2 g/10 min., melting point (DSC peak temperature): 94° C.) |
| Filler | (a) | Surface-treated precipitated calcium carbonate (product name: Calfine YM30; Maruo Calcium; average particle size (micro- |
| | | tracking method): 0.3 μm) |
| | (b) | Precipitated calcium carbonate (product name: CUBE50KAS; Maruo Calcium; average particle size (micro-tracking method): |
| | | 5 μm) |
| | (c) | Crosslinked acryl beads (product name: MX300; Soken Chemical Engineering; average particle size (micro-tracking method): |
| | | 3 μm) |
| | (d) | Cyclic polyolefin copolymer (product name: APL6015, Mitsui Chemicals; average dispersion particle size (electronmicroscope |
| | | observation): 0.8 μm) |
| | (e) | Heavy calcium carbonate (product name: Caltex 7; Maruo Calcium; average particle size (micro-tracking method): 0.97 μm) |
| | (f) | Rutile-type titanium dioxide (product name: Tipaque CR-60; Ishihara Sangyo; average particle size (micro-tracking method): |
| | | 0.2 μm) |

TABLE 2

| | | | | | | | | | | Function imparting |
|---|---|---|---|---|---|---|---|---|---|---|
| | Adhesive layer | | | | | | | | Protective layer | layer |
| Content | (composition (A)) | | | Base layer (composition (B)) | | | | | (composition (C)) | (composition (D)) |
| wt % | Thermoplastic | | Filler | Polypropylene | Other | | Filler | Filler | Material (product | Material (product |
| (Abbreviation) | resin | Filler 1 | 2 | resin | resin | Filler 1 | 2 | 3 | name, manufacturer) | name, manufacturer) |
| Ex. 1 | 100 (PP1) | — | — | 51 (PP1) | 4 (HDPE) | 40 (a) | 5 (f) | — | — | — |
| Ex. 2 | 100 (PP2) | — | — | 51 (PP1) | 4 (HDPE) | 40 (a) | 5 (f) | — | — | — |
| Ex. 3 | 100 (PP1) | — | — | 51 (PP1) | 4 (HDPE) | 40 (a) | 5 (f) | — | — | — |
| Ex. 4 | 100 (PP2) | — | — | 51 (PP1) | 4 (HDPE) | 40 (a) | 5 (f) | — | — | — |
| Ex. 5 | 100 (EVA) | — | — | 51 (PP1) | 4 (HDPE) | 40 (a) | 5 (f) | — | — | — |
| Ex. 6 | 100 (HDPE) | — | — | 66 (PP1) | 4 (HDPE) | 20 (d) | 10 (f) | — | — | — |
| Ex. 7 | 75 (PP2) | 25 (b) | — | 51 (PP1) | 4 (HDPE) | 40 (a) | 5 (f) | — | PET film | — |
| | | | | | | | | | (Diafoil O300E; | |
| | | | | | | | | | Mitsubishi Plastics) | |
| Ex. 8 | 55 (PP2) | 44 (a) | 1 (f) | 51 (PP1) | 4 (HDPE) | 30 (a) | 5 (1) | 10 (e) | PET film | Gas barrierfilm |
| | | | | | | | | | (Diafoil T600E; | (Techbarrier HX; |
| | | | | | | | | | Mitsubishi Plastics) | Mitsubishi Plastics) |
| Ex. 9 | 80 (PP2) | 20 (c) | — | 51 (PP1) | 4 (HDPE) | 40 (a) | 5 (f) | — | PET film | Gas barrierfilm |
| | | | | | | | | | (Diafoil T600E: | (Techbarrier HX; |
| | | | | | | | | | Mitsubishi Plastics) | Mitsubishi Plastics) |
| Ex. 10 | 100 (PP1) | — | — | 65 (PP1) | 10 (HDPE) | 10 (d) | 15 (f) | — | — | — |
| Ex. 11 | 100 (PP1) | — | — | 65 (PP1) | 10 (HDPE) | 25 (f) | — | — | — | — |
| Com. Ex. 1 | Polyester film (product name: E20; thickness 100 μm; Toray) | | | | | | | | | |
| Com. Ex. 2 | 40 (PP1) | 60 (a) | — | 51 (PP1) | 4 (HDPE) | 40 (a) | 5 (f) | — | — | — |
| Com. Ex. 3 | 100 (PP1) | — | — | 51 (PP1) | 4 (HDPE) | 40 (a) | 5 (f) | — | — | — |
| Com. Ex. 4 | 100 (PP1) | — | — | 51 (PP1) | 4 (HDPE) | 40 (a) | 5 (f) | — | — | — |

| | | | | | | Base layer stretch rate | | |
|---|---|---|---|---|---|---|---|---|
| Mold | Back sheet | Thickness (μm) | | Porosity (%) | | (factor) | | Surface |
| conditions | layer configuration | Individual layer | Total layer | Adhesive layer | Base layer | Longitudinal | Transverse | treatment |
| Ex. 1 | A/B | 20/80 | 100 | 0 | 43 | 4.0 | 8.5 | Present |
| Ex. 2 | A/B | 30/150 | 180 | 0 | 50 | 4.2 | 9.0 | Present |
| Ex. 3 | A/B | 20/80 | 100 | 0 | 43 | 4.0 | 8.5 | Present |
| Ex. 4 | A/B | 20/90 | 110 | 0 | 52 | 4.2 | 9.0 | Absent |
| Ex. 5 | A/B | 20/80 | 100 | 0 | 43 | 4.0 | 8.5 | Absent |
| Ex. 6 | A/B | 20/70 | 90 | 0 | 26 | 3.8 | 8.5 | Present |
| Ex. 7 | A/B/C | 20/80/100 | 200 | 0 | 43 | 4.0 | 8.5 | Present |
| Ex. 8 | A/B/D/C | 13/100/12/50 | 175 | 3 | 43 | 4.0 | 8.5 | Present |
| Ex. 9 | A/B/D/C | 13/65/12/50 | 140 | 1 | 42 | 4.0 | 8.5 | Present |
| Ex. 10 | A/B | 10/110 | 120 | 0 | 21 | 4.2 | 9.0 | Present |
| Ex. 11 | A/B | 15/95 | 110 | 0 | 5 | 4.0 | 8.5 | Present |
| Com. Ex. 1 | Polyester film (product name: E20; thickness 100 μm; Toray) | | | | | | | |
| Com. Ex. 2 | A/B | 20/80 | 100 | 6 | 43 | 4.0 | 8.5 | Present |
| Com. Ex. 3 | A/B | 20/50 | 70 | 0 | 18 | 3.5 | 8.0 | Present |
| Com. Ex. 4 | A/B | 20/80 | 100 | 0 | 56 | 4.5 | 9.0 | Present |

TABLE 3

| | | Partial discharge | | | |
|---|---|---|---|---|---|
| | | voltage | | Peel force | |
| | Reflectance | Total | Per | (N/25 mm) | |
| | at 750 nm | thickness | thickness | Longi- | Trans- |
| Evaluation | (%) | (V) | (V/μm) | tudinal | verse |
| Ex. 1 | 96.2 | 1010 | 10.1 | 71 | 75 |
| Ex. 2 | 98.3 | 1430 | 7.9 | 78 | 82 |
| Ex. 3 | 96.2 | 1008 | 10.1 | 31 | 35 |
| Ex. 4 | 97.0 | 853 | 7.8 | 90 | 95 |
| Ex. 5 | 96.2 | 753 | 7.5 | 92 | 98 |
| Ex. 6 | 93.6 | 980 | 10.9 | 88 | 90 |
| Ex. 7 | 96.2 | 1540 | 7.7 | 75 | 78 |
| Ex. 8 | 96.6 | 1350 | 7.7 | 72 | 74 |
| Ex. 9 | 95.4 | 1043 | 7.5 | 80 | 85 |
| Ex. 10 | 93.3 | 950 | 7.9 | 81 | 85 |
| Ex. 11 | 90.5 | 892 | 8.1 | 80 | 84 |
| Com. Ex. 1 | 85.4 | 685 | 6.9 | 92 | 95 |
| Com. Ex. 2 | 96.2 | 1012 | 10.1 | 6 | 8 |
| Com. Ex. 3 | 88.7 | 510 | 7.3 | 68 | 71 |
| Com. Ex. 4 | 93.2 | 1150 | 11.5 | 4 | 5 |

The reflectance and the partial discharge voltage of the present invention are achievable when the base layer of Examples above contains 35% polypropylene resin and 65% filler. However, the mechanical strength, and other advantageous effects of the present invention are more desirable in Examples 1 to 11. The partial discharge voltage of the present invention cannot be realized, and the mechanical strength becomes poor when the base layer of the Examples above contains 25% polypropylene resin and 75% filler.

The reflectance and the partial discharge voltage of the present invention are achievable when the base layer of the Examples above contains 92% polypropylene resin and 8% filler. However, the advantageous effects of the present invention are more desirable in Examples 1 to 11. The reflectance of the present invention cannot be realized when the base layer of the examples above contains 98% polypropylene resin and 2% filler.

### INDUSTRIAL APPLICABILITY

The solar-cell back sheet of the present invention has excellent reflectance, and can improve the power exchange efficiency of a solar cell by effectively reusing the incident light on the solar cell module. Further, because the base layer in the solar-cell back sheet of the present invention is made of a nonpolar polypropylene resin, the solar-cell back sheet has sufficiently high partial discharge voltage by itself, and can be reduced in thickness. Taken together, the solar-cell back sheet of the present invention is highly effective at reducing the cost of generating electricity.

The back sheet hardly undergoes discoloration due to short-wavelength light (ultraviolet rays) as compared with a back sheet that uses a polyester film, and is less likely to lower reflectance even after long use. Further, the adhesive layer forming the back sheet can improve adhesion for the sealing material, and can maintain the solar cell module over extended time periods. Taken together, the solar-cell back sheet of the present invention can maintain the solar cell performance over extended time periods, and is highly useful.

### DESCRIPTION OF REFERENCE NUMERALS AND SIGNS

1 Base layer
2 Adhesive layer
3 Sealing material
4 Solar cell cells
5 Glass plate

1. A solar-cell back sheet comprising a laminate of at least an adhesive layer and a base layer,
wherein the adhesive layer contains 50 to 100% by weight of a thermoplastic resin, and 0 to 50% by weight of at least one of an inorganic filler and an organic filler,
wherein the base layer contains 30 to 95% by weight of a polypropylene resin, and 5 to 70% by weight of at least one of an inorganic filler and an organic filler, and is stretched in at least one direction, and has a porosity of 55% or less, and
wherein the laminate has a reflectance of 90% or more for light of 750 nm wavelength at a surface on the side of the adhesive layer as measured according to the method described under condition d of JIS-Z8722, and a partial discharge voltage of 7.5 V or more per micrometer of laminate thickness as measured according to the method described in IEC-60664-1.

2. The solar-cell back sheet according to claim 1, wherein the base layer have a porosity of 3 to 53%.

3. The solar-cell back sheet according to claim 1, wherein that base layer have a thickness of 70 to 250 μm.

4. The solar-cell back sheet according to claim 1, wherein the inorganic filler and the organic filler in the base layer have an average particle diameter or an average dispersion particle diameter of 0.05 to 0.9 μm.

5. The solar-cell back sheet according to claim 1, wherein the adhesive layer have a porosity of 0 to 3%.

6. The solar-cell back sheet according to claim 1, wherein thermoplastic resin in the adhesive layer be at least one of a polyethylene resin having a melting point of less than 150° C., a random polypropylene resin having a melting point of less than 150° C., and an ethylene-vinyl acetate copolymer resin having a melting point of less than 150° C.

7. The solar-cell back sheet according to claim 1, wherein the thermoplastic resin in the adhesive layer be alternatively a polypropylene resin having a melting point of 150° C. or more.

8. The solar-cell back sheet according to claim 7, wherein the back sheet include a surface treatment layer of primarily acrylic acid ester-based resin or polyethyleneimine-based resin on the surface on the side of the adhesive layer.

9. The solar-cell back sheet according to claim 1, wherein the surface of the side of the adhesive layer be in contact with a sealing material made of ethylene-vinyl acetate copolymer resin.

10. The solar-cell back sheet according to claim 1, wherein the peel force between the adhesive layer and the sealing material be 20 N/25 mm or more.

11. The solar-cell back sheet according to claim 1, wherein the back sheet further include a resin film containing at least one of a polyester-based resin and a fluororesin, or an aluminum foil laminated on one surface or both surfaces of the laminate.
